(19) United States
(12) Patent Application Publication
(10) Pub. No.: US 2020/0093027 A1
(43) Pub. Date: Mar. 19, 2020

(54) SUBSTRATE PLACEMENT MECHANISM, FILM FORMING APPARATUS, AND FILM FORMING METHOD

(71) Applicant: Tokyo Electron Limited, Tokyo (JP)

(72) Inventor: Einstein Noel Abarra, Tokyo (JP)

(21) Appl. No.: 16/568,493

(22) Filed: Sep. 12, 2019

(30) Foreign Application Priority Data
Sep. 14, 2018 (JP) 2018-172375

(51) Int. Cl. H05K 7/20; F25D 25/02; H01L 21/687; H01L 43/12; C23C 14/54; C23C 14/34

(52) U.S. Cl. CPC H05K 7/20009; F25D 25/027; H01L 21/68764; C23C 14/34; H01L 43/12; C23C 14/541; H05K 7/20372

(57) ABSTRACT

A substrate placement device includes a stage having a substrate placement surface on which a substrate is placed, a cooling head provided to face the stage and configured to be cooled to an extremely low temperature by a refrigerator, a contact/separation mechanism configured to cause the stage and the cooling head to be brought into contact with or separated from each other, a rotation mechanism configured to rotate the stage, and a controller. The controller is configured to: cause, except during the film formation, the stage and the cooling head to be in a state where the stage and the cooling head are brought into contact with each other to place the substrate on the stage in that state; and cause, during the film formation, the stage to rotate in a state where the stage and the cooling head are separated from each other by the contact/separation mechanism.

### CROSS-REFERENCE TO RELATED APPLICATIONS

This application is based on and claims priority from Japanese Patent Application No. 2018-172375, filed on Sep. 14, 2018, with the Japan Patent Office, the disclosures of which are incorporated herein in their entireties by reference.

### TECHNICAL FIELD

The present disclosure relates to a substrate placement mechanism, a film forming apparatus, and a film forming method.

### BACKGROUND

There is a processing apparatus for processing a substrate such as, for example, a semiconductor substrate (e.g., a film forming apparatus) that performs a process requiring an extremely low temperature. For example, there is known a technique of forming a magnetic film under an ultra-high vacuum and cryogenic environment in order to obtain a magnetoresistive element having a high magnetoresistance ratio.

As a technique for processing a substrate at an extremely low temperature, Japanese Patent Laid-Open Publication No. 2015-226010 discloses a technique of cooling a substrate to an extremely low temperature using a cooling processing apparatus and then forming a magnetic film on the cooled substrate at an extremely low temperature using a separately provided film forming apparatus.

In addition, U.S. Pat. No. 8,776,542 discloses a technique that performs cooling and film forming processes of a substrate in the same container. The film forming apparatus of U.S. Pat. No. 8,776,542 includes a PVD chamber, a cooling stage provided therein, a rotary stage member rotatably supporting a substrate in a state close to the cooling stage, and a mechanism that supplies a cryogenic cooling gas to a space between the cooling stage and the substrate. In the film forming apparatus, it is possible to uniformly form a PVD film in a rotating state while cooling the substrate.

Further, Japanese Patent Laid-Open Publication No. 2006-073608 discloses a technique in which a cooling head cooled by a refrigerator is provided in a vacuum chamber, a cooling stage as a support for supporting a substrate is fixed to the cooling head, and thin film formation is performed while cooling the substrate to an extremely low temperature on the cooling stage.

### SUMMARY

A substrate placement mechanism according to an aspect of the present disclosure is configured to place thereon a substrate on which film formation is performed in a film forming apparatus. The substrate placement mechanism includes: a stage having a substrate placement surface on which the substrate is placed; a cooling head provided to face a side of the stage opposite to the substrate placement surface, and configured to be cooled to an extremely low temperature by a refrigerator; a contact/separation mechanism configured to cause the stage and the cooling head to be brought into contact with or separated from each other; a rotation mechanism configured to rotate the stage; and a controller. The controller is configured to: cause, except during the film formation, the substrate to be placed on the stage in a state where the stage and the cooling head are brought into contact with each other by the contact/separation mechanism; and cause, during the film formation, the stage to be rotated by the rotation mechanism in a state where the stage and the cooling head are separated from each other by the contact/separation mechanism.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating an exemplary film forming apparatus including a substrate placement mechanism according to a first embodiment.

FIG. 2 is a flowchart illustrating an exemplary film forming method in a film forming apparatus including the substrate placement mechanism according to the first embodiment.

FIG. 3 is a cross-sectional view illustrating a state where a stage and a cooling head are in contact with each other in the substrate placement mechanism according to the first embodiment.

FIG. 4 is a cross-sectional view illustrating a substrate placement mechanism according to a second embodiment.

FIG. 5 is a cross-sectional view illustrating a substrate placement mechanism according to a third embodiment.

FIG. 6 is a cross-sectional view illustrating a substrate placement mechanism according to a fourth embodiment.

FIG. 7 is a cross-sectional view illustrating a contact/separation structure and a contact/separation mechanism of the substrate placement mechanism according to the fourth embodiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

### First Embodiment

First, a first embodiment will be described.

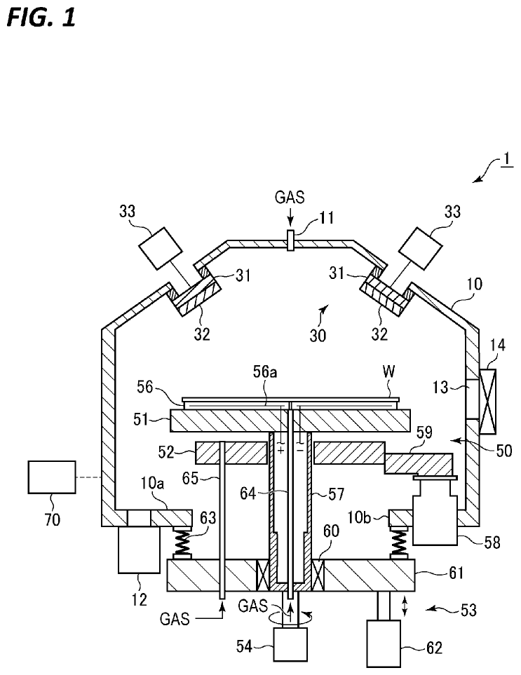

FIG. 1 is a cross-sectional view illustrating an exemplary film forming apparatus including a substrate placement mechanism according to a first embodiment.

A film forming apparatus to which the substrate placement mechanism according to the present embodiment is applied is formed as a film forming apparatus for forming a film on a substrate by sputtering under an ultra-high vacuum and cryogenic environment. The film formed under such a cryogenic environment may be, for example, a magnetic film used for a tunneling magneto-resistance (TMR) element. The substrate may be, for example, a semiconductor wafer, but is not limited thereto.

As illustrated in FIG. 1, a film forming apparatus 1 has a vacuum container 10, a sputtered particle emitting unit 30, a substrate placement mechanism 50, and a controller 70.

The vacuum container 10 is configured to accommodates a substrate W therein and to be capable of reducing the pressure therein to an ultra-high vacuum (e.g., 10⁻⁵ Pa or less). In the upper portion of the processing container, side surfaces are inclined. At the top of the vacuum container 10, a gas inlet port 11 is provided. A gas supply pipe (not illustrated) is connected to the gas inlet port 11, and a gas required for sputtering film formation (e.g., a rare gas such as argon, krypton, or neon, or nitrogen gas) is supplied from the gas supply pipe. Further, an exhaust mechanism 12 having a vacuum pump capable of reducing the pressure inside the vacuum container 10 to an ultra-high vacuum is connected to the bottom of the vacuum container 10. In addition, a loading/unloading port 13 for loading and unloading a substrate is formed in the side wall of the vacuum container 10. The loading/unloading port 13 is opened/closed by a gate valve 14. By opening the gate valve 14, the vacuum container 10 communicates with a transport chamber (not illustrated) adjacent thereto, and a substrate W is loaded/unloaded by a transport apparatus (not illustrated) in the transport chamber.

The sputtered particle emission unit 30 has a plurality of (two in the drawing) target holders 31, a plurality of targets 32 held by respective target holders 31, and a plurality of power supplies 33 configured to apply a voltage to respective target holders 31.

The target holders 31 are made of a conductive material, and are attached to the upper inclined surfaces of the vacuum container 10 via insulating members, respectively. The target holders 31 holds the targets 32 such that the targets 32 are positioned obliquely upward with respect to a substrate W held by a substrate placement mechanism 50 described later.

The targets 32 are made of a material containing a constituent element of a film to be formed. For example, in the case of forming a magnetic film (a film containing a ferromagnetic substance such as Ni, Fe, or Co), for example, CoFe, FeNi, or NiFeCo may be used as the material for the targets 32.

The plurality of power supplies 33 are electrically connected to the plurality of target holders 31, respectively. By applying a voltage (e.g., a DC voltage) to the target holders 31 from the power supplies 33, a sputtering gas is dissociated around the targets 32. Then, ions in the dissociated sputtering gas collide with the targets 32, and sputtered particles, which are particles of the constituent material, are released from the targets 32.

There may be one target holder 31 and one target 32.

The substrate placement mechanism 50 includes a stage configured to place a substrate W thereon, a cooling head 52 provided below the stage 51 and cooled by a refrigerator 58, a contact/separation mechanism 53 configured to cause the stage 51 and the cooling head 52 to be brought into contact with or separated from each other, and a rotation mechanism 54 configured to rotate the stage 51. The stage 51 has a substrate placement surface on the upper surface thereof, and the surface opposite to the substrate placement surface faces the upper surface of the cooling head 52.

The stage 51 has a plate shape having a diameter slightly larger than that of the substrate W, and is made of a material having high thermal conductivity. Copper (pure copper) is preferable as the material having high thermal conductivity, but other high-thermal conductivity materials such as, for example, aluminum, may be used. For example, the thickness of the stage 51 is defined so as to have a sufficiently large heat capacity compared to the substrate W. The thickness of the stage 51 may be 20 mm or more, and may be 30 mm or more. The stage 51 has an electrostatic chuck 56 for attracting the substrate W. The electrostatic chuck 56 has a substrate placement surface, electrodes 56a are embedded in a dielectric, and a DC voltage is applied to the electrodes 56a to attract the substrate W placed on the placement surface by an electrostatic force. The stage 51 is supported by a cylindrical support 57 extending downward from the center of the lower surface thereof.

From the viewpoint of suppressing heat loss from the stage 51, the support 57 is made of a material having lower thermal conductivity (e.g., stainless steel) compared to the high thermal conductivity material constituting the stage 51 (e.g., copper or aluminum), and is formed to be very thin.

The cooling head 52 is configured as an annular plate, and is for cooling the substrate W via the stage 51. The cooling head 52 is held by the refrigerator 58 via a heat transfer unit 59. The upper surface of the cooling head 52 is cooled to an extremely low temperature (e.g., −30° C. or less) by heat transfer of cold heat from the refrigerator 58. The cooling head 52 is made of a material having high thermal conductivity from the viewpoint of efficiently cooling the stage 51. Copper (pure copper) is preferable as the material having high thermal conductivity, but other high-thermal conductivity materials such as, for example, aluminum, may be used. The refrigerator 58 is fixed to the bottom wall 10a of the vacuum container 10, and the position of the cooling head 52 is also fixed accordingly. The refrigerator 58 may be of a type utilizing a Gifford-McMahon (GM) cycle from the viewpoint of cooling performance. When forming a magnetic film used for a TMR element, the cooling temperature of the cooling head 52 by the refrigerator 58 may be in the range of −123 to −223° C. (150 to 50 K).

The contact/separation mechanism 53 includes a lift plate 61 to which the lower end portion of the support body 57 is rotatably fitted via the bearing 60 and which is movable up and down, and an actuator configured to move the stage 51 up and down via the lift plate 61 and the support 57. The space between the support 57 and the lift plate 61 is sealed by a magnetic fluid. The lift plate 61 is provided below the bottom wall 10a of the vacuum container 10. An opening 10b is formed in the center of the bottom wall 10a to correspond to the lift plate 61, and the space between the bottom wall 10a and the lift plate 61 is sealed by a bellows 63. The contact/separation mechanism 53 causes the cooling head 52 and the stage 51 to be brought into contact with or separated from each other by raising and lowering the lift plate 61 between a contact position which is the lowered position and a processing position which is the raised position. Specifically, by positioning the stage 51 at the contact position via the lift plate 61, the stage 51 is brought into contact with the cooling head 52, and the substrate W is capable of being cooled to an extremely low temperature via the stage 51. In addition, by positioning the stage 51 at the processing position via the lift plate 61, the stage 51 is separated from the cooling head 52, and thus it becomes possible to perform a film forming process while rotating the substrate W. The processing position of the stage 51 is appropriately adjusted such that the sputtered particles are appropriately incident on the substrate W. FIG. 1 illustrates the state when the film forming process is being performed.

The rotation mechanism 54 is provided below the support 57, and is configured with a rotation motor. The rotation mechanism 54 is configured to rotate the substrate W placed on the stage 51 by rotating the stage 51 via the support 57. In the state where the substrate W is rotated by the rotation mechanism 54, the sputtered particles emitted obliquely from the target of the sputtered particle emission unit 30 are uniformly deposited on the substrate W.

A gas pipe 64 is provided inside the support 57 to extend upward from below the vacuum container 10 to reach the upper surface of the electrostatic chuck 56. A heat transfer gas is supplied between the electrostatic chuck 56 and the substrate W. In addition, a gas pipe 65 is provided to extend upward from below the vacuum container 10 to reach the upper surface of the electrostatic chuck 52. From the gas pipe 65, a heat transfer gas is supplied between the stage 51 and the cooling head 52 when the stage 51 and the cooling head 52 are in contact with each other. Helium gas having high thermal conductivity may be used as the heat transfer gas. Instead of helium gas, argon gas may be used.

The controller 70 is configured with a computer, and controls respective components of the film forming apparatus 1, for example, the power supply 33 of the sputtered particle emission unit 30, the exhaust mechanism 12, the rotation mechanism 54, and the actuator 62. The controller 70 also serves as a controller of the substrate placement mechanism. The controller 70 has a main controller including a CPU that actually performs these components, an input device, an output device, a display device, and a storage device. The storage device stores parameters of various processes to be executed by the film forming apparatus 1, and is configured such that a storage medium, which is stored with a program for controlling the processes to be executed by the film forming apparatus 1, that is, a processing recipe is set thereto. The main controller of the controller 70 calls a predetermined processing recipe stored in the storage medium, and causes the film forming apparatus 1 to execute a predetermined process on the basis of the processing recipe.

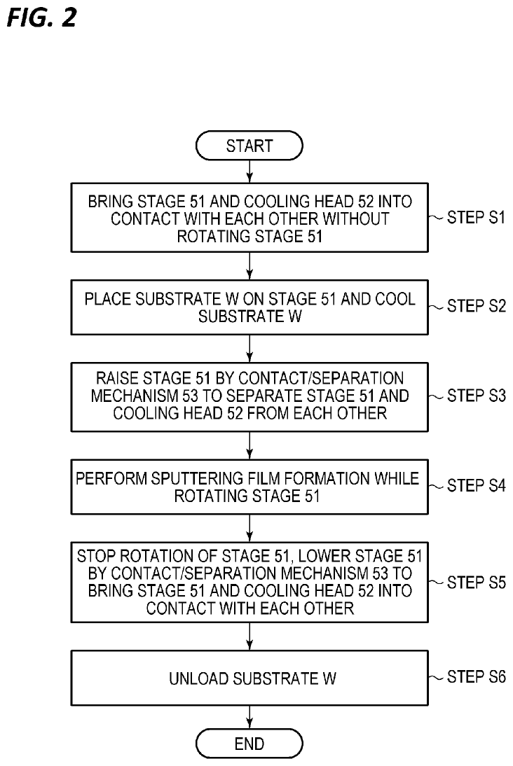

Next, the film forming method in the film forming apparatus 1 configured as described above is described. FIG. 2 is a flowchart illustrating an exemplary film forming method in the film forming apparatus 1.

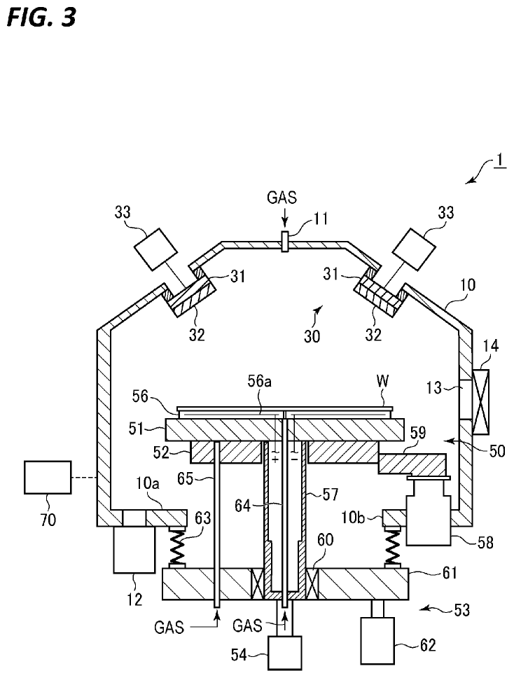

First, as illustrated in FIG. 3, the stage 51 is positioned at the contact position which is the lowered position by the contact/separation mechanism 53 to bring the stage 51 and the cooling head 52 into contact with each other without rotating the stage 51 (step S1). In this state, the cooling power of the cooling head 52 kept at an extremely low temperature by the refrigerator 58 is directly supplied to the stage 51 by thermal conduction to be heat-exchanged, and the stage 51 is cooled to a desired very low temperature in a relatively short time. The cooling temperature at this time may be −123 to −223° C. (150 to 50 K), for example −173° C. (100 K). At this time, a heat transfer gas is supplied to the space between the stage 51 and the cooling head 52 via the gas pipe 65. Since microscopic irregularities are formed microscopically on the surfaces of the stage 51 and the cooling head 52 and the contact area therebetween is small, the heat transfer gas is supplied to the space therebetween to assist heat transfer.

Next, the gate valve 14 is opened, a substrate W is placed on the stage 51 by the transport apparatus of the transport chamber (not illustrated), and the substrate W is cooled (step S2). Specifically, the substrate W is delivered onto the lift pins in a state where the lift pins are raised, and the substrate W is placed on the electrostatic chuck 56 of the stage 51 by lowering the lift pins. The substrate W is electrostatically attracted by applying a DC voltage to the electrodes of the electrostatic chuck 56.

At this time, the substrate W is cooled by heat exchange with the cooling head 52 via the stage 51 by holding the substrate W on the stage 51 for a predetermined length of time. The heat transfer gas is supplied to the rear surface of the substrate W via the gas pipe 64 to increase heat transfer from substrate W to stage 51.

After the substrate W is cooled, the stage 51 is raised by the contact/separation mechanism 53 to separate the stage 51 and the cooling head 52 from each other (step S3). At this time, the height position of the stage 51 is adjusted to be the processing position.

Then, a sputtering gas is introduced into the vacuum container 10 from the gas inlet port 11, the inside of the vacuum container 10 is controlled to a predetermined pressure by the exhaust mechanism 12, and the sputtering film formation is performed while rotating the stage 51 by the rotation mechanism 54 (step S4).

The sputtering film formation is performed by applying a voltage from the power supply 33 to the target holders 31 and causing ions in the sputtering gas dissociated around the targets 32 to collide with the targets 32. That is, when ions collide with the targets 32, sputtered particles are released, and the sputtered particles are obliquely incident on the surface of the substrate W and deposited on the substrate W. Thus, it is possible to perform uniform film formation by causing sputtered particles to be obliquely incident on the substrate W and performing film formation while rotating the substrate W together with the stage 51.

After the film forming process is completed, the rotation of the stage 51 is stopped, and the stage 51 is lowered by the contact/separation mechanism 53 and positioned at the contact position to bring the stage 51 into contact with the cooling head 52 (step S5). In this state, the stage 51 is cooled by the cooling head 52.

Thereafter, the heat transfer gas is removed and the substrate W subjected to the film forming process is raised by the lift pins of the stage 51, and the substrate W is unloaded by the transport apparatus of the transport chamber (step S6).

Thus, the processing of one substrate W is completed. The sputtering film formation and the cooling of the substrate W may be repeated from the viewpoint of reliably cooling the substrate W to an extremely low temperature.

While maintaining the state where the stage 51 and the cooling head 52 are in contact with each other, the substrate W is placed on the stage 51 as described above and subjected to a film forming process.

According to the present embodiment, the stage 51 is brought into contact with the cooling head 52 maintained at an extremely low temperature by the refrigerator 58, and the substrate W is placed on the stage 51 in that state. Since the stage 51 is in contact with the cooling head 52, the stage 51 is uniformly cooled to an extremely low temperature in a short time. Therefore, since heat is capable of being efficiently exchanged between the substrate W and the stage 51 even in the state where the thermal load for placing the substrate W at a normal temperature on the stage 51 is high, it is possible to efficiently and uniformly cool the substrate W to an extremely low temperature.

In addition, when the film forming process is performed on the substrate W, since the stage 51 and the cooling head 52 are separated by the contact/separation mechanism 53, the stage 51 is capable of being rotated by the rotation mechanism 54. For this reason, since it is possible to perform sputtering film formation while rotating the substrate W, it is possible to uniform film formation. During the film formation, the stage 51 is separated from the cooling head 52 and thus the stage 51 is not cooled. However, since the heat capacity of the stage 51 is sufficiently large compared to the substrate W, it is possible to perform a film forming process while suppressing the temperature rise of the substrate W which is being subjected to sputtering film formation.

Furthermore, except during the film forming process, since the stage 51 is in contact with the cooling head 52 and thus the stage 51 is cooled, it is possible to maximize the cooling time of the stage 51 and it is possible to reduce the temperature fluctuation of the stage 51. For this reason, it is possible to stably maintain the stage 51 at an extremely low temperature, and to rapidly and stably maintain the substrate W placed on the stage 51 at a desired very low temperature.

In the technique of Japanese Patent Laid-Open Publication No. 2015-226010, since the cooling apparatus and the film forming apparatus are provided separately, it is difficult to sufficiently lower the temperature at film formation, and the number of apparatuses (chambers) increases.

In addition, in the technique of U.S. Pat. No. 8,776,542, a substrate is capable of being cooled to an extremely low temperature in a film forming apparatus, and furthermore, uniform film formation is capable of being performed while rotating the substrate. However, since the rotating stage member supporting the substrate and the cooling stage cooled to an extremely low temperature are separated from each other and the cooling gas is supplied to the space between the stage member and the cooling stage, it is difficult to efficiently cool the substrate via the gas. In addition, the temperature of the substrate is likely to rise during sputtering film formation. In order to increase the cooling efficiency, it is considered, for example, to make the rotary stage member and the cooling stage as close as possible, or to use a large refrigerator. However, the apparatus costs increase and the apparatuses become large. In the technique of U.S. Pat. No. 8,776,542, it is difficult to uniformly cool the substrate due to the difference in heat capacity between the portion where the substrate is held and the portion where the substrate is not held.

In addition, in the technique of Japanese Patent Laid-Open Publication No. 2006-073608, since the cooling stage as a support for supporting the substrate is fixed to the cooling head cooled by the refrigerator, it is possible to cool the substrate an extremely low temperature on the cooling stage. However, it is impossible to rotate the substrate.

In contrast, in the present embodiment, as described above, the stage 51 and the cooling head 52 are separated from each other and the stage 51 is rotated when performing the film forming process, and in the other cases, the stage 51 and the cooling head 52 are brought into contact with each other. Therefore, even if the substrate at a normal temperature is placed on the stage 51, it is possible to efficiently and uniformly cool the substrate W to an extremely low temperature, it is possible to rotate the substrate W together with the stage 51 in the film forming process, and only a slight increase in substrate temperature exists at that time. Therefore, it is possible to perform uniform film formation at an extremely low temperature.

### Second Embodiment

Next, a second embodiment will be described.

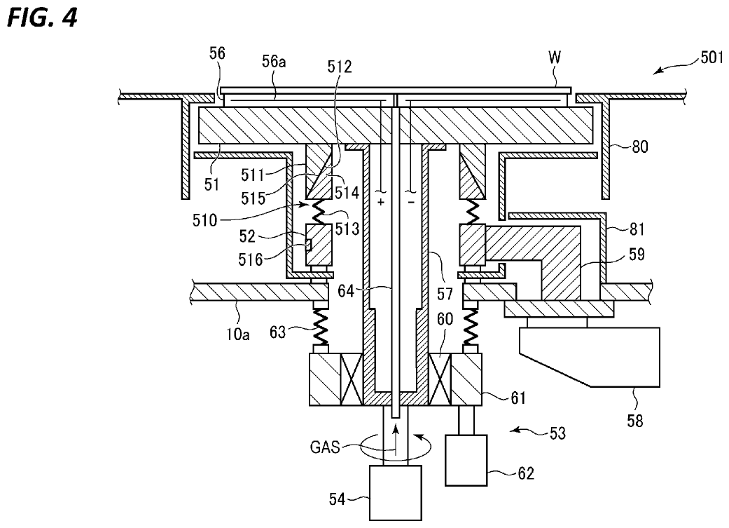

FIG. 4 is a cross-sectional view illustrating a substrate placement mechanism according to a second embodiment.

Similar to the substrate placement mechanism 50 of the first embodiment, the substrate placement mechanism 501 according to the present embodiment is also applied to a sputtering film forming apparatus. The basic configuration of the substrate placement mechanism 501 according to the present embodiment is the same as that of the substrate placement mechanism 50 of the first embodiment. Thus, the same components as those in FIG. 1 will be denoted by the same reference numerals and descriptions thereof will be omitted.

In the present embodiment, a contact/separation structure 510 is provided between the stage 51 and the cooling head 52 to be used for contact/separation of the stage 51 and the cooling head 52. The contact/separation structure 510 has an annular inner tapered member 511 as a first member on the stage 51 side, and an annular outer tapered member 514 as a second member on the cooling head 52 side. The inner tapered member 511 has an inner tapered surface connected to the lower surface of the stage 51 and having a diameter increasing downward. The outer tapered member 514 has an outer tapered surface connected to the upper surface of the cooling head 52 via a bellows 513 and having diameter increasing toward the lower surface. In addition, the cooling head 52 is provided with a heater 516 for temperature control. The inner tapered member 511, the bellows 513, and the outer tapered member 514 are all made of a metal having high thermal conductivity such as, for example, copper or aluminum.

In the contact/separation structure 510, by raising/lowering the stage 51 by the contact/separation mechanism 53, a state where the inner tapered member 511 which is the first member on the stage 51 side and the outer tapered member 514 which is the second member on the cooling head 52 side are brought into contact with each other, or a state where the inner tapered member 511 and the outer tapered member 514 are separated from each other is formed. This causes the stage 51 and the cooling head 52 to be brought into contact with or separated from each other. Specifically, by positioning the stage 51 at the contact position, which is the lowered position, the inner tapered surface 512 of the inner tapered member 511 and the outer tapered surface 515 of the outer tapered member 514 are in contact with each other, and the stage 51 and the cooling head 52 are in contact with each other via the contact/separation structure 510. In addition, by positioning the stage 51 at the processing position, which is the raised position, the inner tapered member 511 and the outer tapered member 514 are separated from each other, and the stage 51 and the cooling head 52 are separated from each other. This enables the stage 51 to be rotated.

In the present embodiment, since the contact surface between the inner tapered member 511 and the outer tapered member 514 is a tapered surface, the contact area is relatively large, and the contact pressure is large. Therefore, the contact between the inner tapered member 511 and the outer tapered member 514 is good, and the thermal conduction between the cooling head 52 and the stage 51 via the contact/separation structure 510 is capable of being enhanced so as to promote heat exchange between the cooling head 52 and the stage 51. Furthermore, by providing the bellows 513 between the cooling head 52 and the outer tapered member 514, it is possible to reliably bring the inner tapered surface 512 and the outer tapered surface 515 into contact with each other without any gap due to inclination.

Although the bellows 513 has a small contact area with respect to the cooling head 52 and the outer tapered member 514, since the bellows 513, the cooling head 52, and the outer tapered member 514 are made of a material of high thermal conductivity such as copper or aluminum, it is possible to ensure sufficient thermal conductivity.

In addition, in the present embodiment, a shield member 80 is provided to cover the contact portion between the stage 51 and the cooling head 52. This makes it possible to prevent dust generated by, for example, the contact between the stage 51 and the cooling head 52 (the inner tapered member 511 and the outer tapered member 514) from reaching the film formation area. In addition, a radiation shield 81 is provided around the cooling head 52. The radiation shield 81 may be formed of a material having a low emissivity.

In addition, since the substrate placement mechanism 501 according to the present embodiment is the same as the substrate placement mechanism 50 according to the first embodiment in basic configuration, it is possible to achieve the same basic effect as the substrate placement mechanism 50.

### Third Embodiment

Next, a third embodiment will be described.

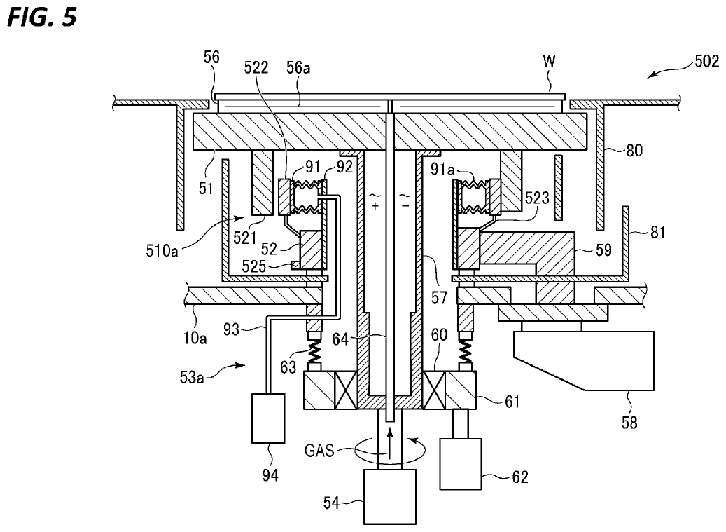

FIG. 5 is a cross-sectional view illustrating a substrate placement mechanism according to a third embodiment.

Similar to the substrate placement mechanism 50 of the first embodiment, the substrate placement mechanism 502 according to the present embodiment is also applied to a sputtering film forming apparatus. The basic configuration of the substrate placement mechanism 502 according to the present embodiment is the same as that of the substrate placement mechanism 50 of the first embodiment and that of the substrate placement mechanism 501 of the second embodiment. Thus, components, which are the same as those in FIGS. 1 and 4 will be denoted by the same reference numerals, and descriptions thereof will be omitted.

In the present embodiment, a contact/separation structure 510 is provided between the stage 51 and the cooling head 52 to be used for contact/separation of the stage 51 and the cooling head 52. The contact/separation structure 510a includes an abutment member 521 provided on the lower surface of the stage 51 as a first member of the stage 51 side and a contact member 522 connected to the cooling head 52 via a flexible member 523 as a second member of the cooling head side. The contact member 522 moves in a horizontal direction to be brought into contact with or separated from an abutment surface inside the abutment member 522. In addition, the cooling head 52 is provided with a heater 525 for temperature control. The abutment member 521, the contact member 522, and the flexible member 523 are all made of a metal having high thermal conductivity such as, for example, copper or aluminum.

The substrate placement mechanism 502 according to the present embodiment has a contact/separation mechanism 53a that causes the contact member 522 to be brought into with or the separated from the abutment member 521 by the pressure of a gas instead of the contact/separation mechanism 53 according to the first and second embodiments.

The contact/separation mechanism 53a includes an expansion/contraction unit 91 that is provided on the rear surface of the contact member 527 to be expanded and contracted by a gas pressure, and a gas supply 94 that supplies the gas into the expansion/contraction unit 91 via a gas supply path 93. The expansion/contraction unit 91 is connected to the cooling head 52 via a connection member 92. The expansion/contraction unit 91 has a space formed therein, and the upper surface and the lower surface are formed of bellows 91a. Since the pressure gas used here needs to be in a gas state at an extremely low temperature, helium gas or argon gas may be used like the heat transfer gas.

In the previous embodiments, the lift plate 61 and the actuator 62 constitute the contact/separation mechanism, but in the present embodiment, these do not constitute the contact/separation mechanism are only used for adjusting the position of the stage 51 during the film forming process.

In the contact/separation structure 510a, the contact/separation mechanism 53a forms a state where the contact member 521 and the contact member 522 are in contact with each other or a state where they are separated from each other. This causes the stage 51 and the cooling head 52 to be brought into contact with or separated from each other.

Specifically, when the gas is supplied into the space of the expansion/contraction unit 91, the bellows 91a of the expansion/contraction unit 91 is expanded by the gas pressure, so that the contact member 522 abuts on the abutment member 521. Thus, the stage 51 and the cooling head 52 are in contact with each other via the contact/separation structure 510a. At this time, since the gas pressure acts evenly on the expansion/contraction unit 91, centering is automatically performed. Meanwhile, by releasing the gas in the space of the expansion/contraction unit 91, the expansion/contraction unit 91 is retracted, and the contact member 522 is separated from the abutment member 521. As a result, the stage 51 and the cooling head 52 are in a separated state, which enables the stage 51 to be rotated.

The flexible member 523 has a small contact area compared to the abutment member 521 and the contact member 522, but copper or aluminum having high thermal conductivity may sufficiently transfer cold heat.

According to the present embodiment, the contact/separation mechanism 53a causes the stage 51 and the cooling head 52 to be brought into contact with or separated from each other by causing the contact member 522 of the contact/separation structure 510a to be brought into contact with or separated from the contact member 521. Therefore, it is possible to miniaturize the contact/separation mechanism 53a. In addition, the stage 51 and the cooling head 52 are capable of being brought into contact with or separated from each other without moving the stage 51.

In addition, since the flexible member 523 is deformable, the movement of the contact member 522 by the expansion/contraction of the expansion/contraction member 91 is performed without any problem. In addition, the contact/separation mechanism 53a is not limited to one using an expansion/contraction member, and may be one that moves the contact member 522 by a drive mechanism such as, for example, a motor.

Since the substrate placement mechanism 502 according to the present embodiment is the same as the substrate placement mechanisms 50 and 501 according to the first and second embodiments in basic configuration, it is possible to achieve the same basic effect as the substrate placement mechanisms 50 and 501.

### Fourth Embodiment

Next, a fourth embodiment will be described.

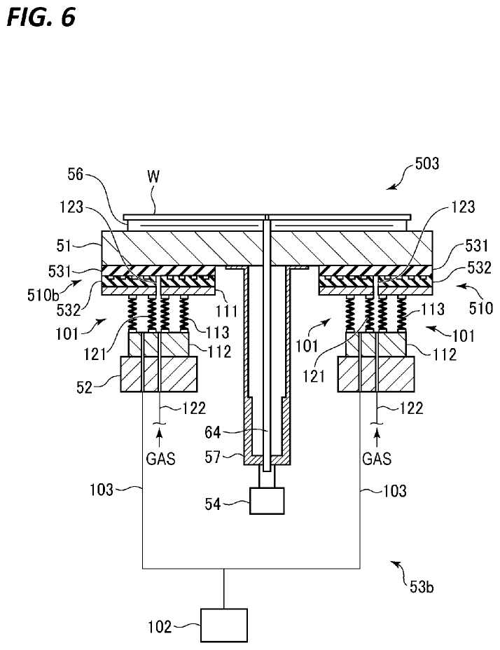

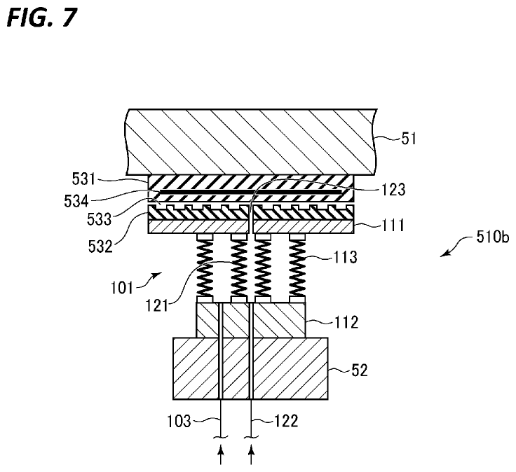

FIG. 6 is a cross-sectional view illustrating a substrate placement mechanism according to a fourth embodiment. FIG. 7 is a cross-sectional view illustrating a contact/separation structure and a contact/separation mechanism of the substrate placement mechanism.

Similar to the substrate placement mechanisms 50, 501, and 502 of the first to third embodiments, the substrate placement mechanism 503 according to the present embodiment is also applied to a sputtering film forming apparatus. The basic configuration of the substrate placement mechanism 503 according to the present embodiment is the same as those of the substrate placement mechanisms 50, 501, and 502 of the first to third embodiments. Thus, components, which are the same as those in FIGS. 1, 4, and 5 will be denoted by the same reference numerals, and descriptions thereof will be omitted.

In the present embodiment, a contact/separation structure 510b is provided between the stage 51 and the cooling head 52 to be used for contact/separation of the stage 51 and the cooling head 52. A plurality of contact/separation structures 510b are provided in the circumferential direction between the stage 51 and the cooling head 52.

Each contact/separation structure 510b includes a first ceramic member 531 bonded to the lower surface of the stage 51 and a second ceramic member 531 disposed below the first ceramic member 532 to face the first ceramic member 532 and connected to the cooling head 52 via the expansion/contraction unit 101 of the contact/separation mechanism 53b to be described later. That is, the first ceramic member 531 functions as a first member on the stage 51 side, and the second ceramic member 532 functions as a second member on the cooling head 52 side.

The contact/separation structure 510b may be formed in an annular shape along the upper surface of the cooling head 52.

In addition, the substrate placement mechanism 503 of the present embodiment has a contact/separation mechanism 53b instead of the contact/separation mechanism 53 of the first and second embodiments and the contact/separation mechanism 53a of the third embodiment.

The contact/separation mechanism 53b includes a plurality of expansion/contraction units 101 provided below the second ceramic member 532 of each contact/separation structure 510b and a common gas supply 102 configured to supply gas to the plurality of expansion/contraction units 101 via a gas supply path 103. Each expansion/contraction unit 101 includes an upper plate 111 bonded to the lower surface of the second ceramic member 532, a lower plate 112 bonded to the upper surface of the cooling head 52, and a bellows 113 provided between the upper plate 111 and the lower plate 112. The upper plate 111, the lower plate 112, and the bellows 113 are made of a material having high thermal conductivity, such as, for example, copper or aluminum.

The gas supply path 103 penetrates the cooling head 52 and the lower plate 112 from the lower surface of the cooling head 52 to reach the space surrounded by the bellows 113, and the expansion/contraction unit 101 is expanded/contracted by supplying gas from the gas supply 102 to the space. As the pressure gas used here, helium gas or argon gas may be used as in the third embodiment.

Although not illustrated, in the present embodiment, the lift plate 61 and the actuator 62 are also used only for adjusting the position of the stage 51a in the film forming process as in the third embodiment.

In the contact/separation structure 510b, the contact/separation mechanism 53b forms a state where the first ceramic member 531 and the second ceramic member 532 are in contact with each other or a state where they are separated from each other. This causes the stage 51 and the cooling head 52 to be brought into contact with or separated from each other.

Specifically, when the gas is supplied into the space of the expansion/contraction unit 101, the bellows 113 of the expansion/contraction unit is expanded by the gas pressure, so that the second ceramic member 532 abuts on the first ceramic member 531. This brings the stage 51 and the cooling head 52 into contact with each other via the expansion/contraction unit 101 and the contact/separation structure 510b. Meanwhile, by releasing the gas in the space of the expansion/contraction unit 101, the expansion/contraction unit 101 is retracted, and the second ceramic member 532 is separated from the first ceramic member 531. As a result, the stage 51 and the cooling head 52 are in a separated state, which enables the stage 51 to be rotated.

Since the ceramic has relatively high thermal conductivity, the thermal conductivity between the first ceramic member 531 and the second ceramic member 532 is capable of being increased when the first ceramic member 531 and the second ceramic member 532 are in contact each other in the contact/separation structure 510b. In addition, the upper plate 111, the lower plate 112, and the bellows 113 of the expansion/contraction unit 101 interposed between the second ceramic member 532 and the cooling head 52 are made of a material having high thermal conductivity such as, for example, copper or aluminum. For this reason, the heat exchange between the cooling head 52 and the stage 51 via the contact/separation structure 510b is good.

The mating surfaces of the first ceramic member 531 and the second ceramic member 532 may be mirror-finished. Since the ceramic has good surface-controllability and little time-dependent deterioration, the contact between the mating surfaces becomes good by mirror-finishing the mating surface, and the thermal conductivity therebetween becomes better. Moreover, the ceramics forming the mating surfaces are preferably as high as possible in thermal conductivity, and alumina, sapphire (single crystal alumina), and aluminum nitride are preferable. These materials have very high thermal conductivity at an extremely low temperature as low as −173° C. (100 K), and in particular, sapphire exhibits higher thermal conductivity than copper at the extremely low temperature.

As illustrated in FIG. 7, a plurality of recesses 533 are formed in the surface of the second ceramic member 532. In the space inside the bellows 113, a small bellows 121 is provided concentrically. A gas supply path 122 for supplying a heat transfer gas, which extends from below the cooling head 52 through the cooling head 52 and the lower plate 112, is connected to the space of the small bellows 121. In addition, a gas flow path 123 is formed in the upper plate 111 and the second ceramic member 532 so as to communicate with the inner space of the small bellows 121. Therefore, it is possible to supply the heat transfer gas to the recesses 533 when the first ceramic member 531 and the second ceramic member 532 are brought into contact with each other. In this way, by supplying the heat transfer gas, the heat transfer by the gas is achieved in addition to the good thermal conduction obtained due to the contact between the first ceramic member 531 and the second ceramic member 532, and thus, it is possible to improve heat exchangeability therebetween.

As shown in FIG. 7, electrodes 534 may be embedded in the first ceramic member 531 and a DC voltage may be applied to the electrodes to electrostatically attract the second ceramic member 532. By mirror-finishing the mating surfaces of the first ceramic member 531 and the second ceramic member 532, and by electrostatically attracting the mating surfaces, it is possible to perform better heat exchange. An electrode may be provided in the second ceramic member 532.

In the case where the mating surfaces of the first ceramic member 531 and the second ceramic member 532 are mirror-finished, or in the case where the mating surfaces are electrostatically attracted in addition to the mirror-surface machining, the adsorption force between the mating surfaces is too strong, which may make it difficult to separate the mating surfaces. However, even in such a case, the mating surfaces may be easily separated by supplying the heat transfer gas to the recesses 533 and using the pressure of the gas.

Thus, in the present embodiment, it is possible to further enhance heat exchangeability by mirror-finishing the mating surfaces of the first ceramic member 531 and the second ceramic member 532, selecting a ceramic material, using a heat transfer gas, and using electrostatic attraction. As a result, it is possible to further enhance the heat exchangeability between the cooling head 52 and the stage 51 via the contact/separation structure 510b, and it is also possible to further enhance the cooling performance of the stage and hence the cooling performance of the substrate W.

### Other Applications

For example, the substrate placement mechanisms according to the first to fourth embodiments are merely examples, and the configuration is not particularly limited as long as the stage and the cooling head are configured to be brought into contact with or separated from each other by the contact/separation mechanism and the stage is configured to be rotatable when the stage and the cooling head are separated from each other. Moreover, the film-forming apparatus is also merely an illustration.

According to the present disclosure, a substrate placement mechanism, a film forming apparatus, and a film forming method are provided in which it is possible to efficiently and uniformly cool a substrate in the film forming apparatus, and it is also possible to rotate the substrate placed on the stage during film formation.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate placement device that places thereon a substrate on which film formation is performed in a film forming apparatus, the substrate placement device comprising:
a stage having a substrate placement surface on which the substrate is placed;
a cooling head provided to face a side of the stage opposite to the substrate placement surface, and configured to be cooled to an extremely low temperature by a refrigerator;
a contact/separation plate configured to cause the stage and the cooling head to be brought into contact with or separated from each other;
a rotator configured to rotate the stage; and
a controller,
wherein the controller is configured to: cause, except during the film formation, the substrate to be placed on the stage in a state where the stage and the cooling head are brought into contact with each other by the contact/separation plate; and cause, during the film formation, the stage to be rotated by the rotator in a state where the stage and the cooling head are separated from each other by the contact/separation plate.

2. The substrate placement device according to claim 1, wherein the stage includes an electrostatic chuck configured to attract the substrate.

3. The substrate placement device according to claim 1, wherein the contact/separation mechanism causes the stage and the cooling head to be brought into contact with or separated from each other by an actuator.

4. The substrate placement device according to claim 1, wherein the stage has a heat capacity substantially larger than that of the substrate.

5. The substrate placement device according to claim 1, further comprising:
a gas supply source configured to supply a heat transfer gas between the stage and the cooling head in the state where the stage and the cooling head are brought into direct contact with each other.

6. The substrate placement device according to claim 1, further comprising:
a contact/separation structure provided between the stage and the cooling head and having a first member on a side of the stage and a second member on a side of the cooling head, the first member and the second member being brought into contact with or separated from each other by the contact/separation mechanism.

7. The substrate placement device according to claim 6, wherein a contact surface between the first member and the second member is a tapered surface.

8. The substrate placement device according to claim 7, wherein the second member is connected to the cooling head via a bellows.

9. The substrate placement device according to claim 6, wherein the first member is an abutment member provided on a lower surface of the stage and having an abutment surface therein, and the second member is a contact member that moves horizontally to be brought into contact with or separated from the abutment surface of the abutment member.

10. The substrate placement device according to claim 9, wherein the contact/separation plate includes an expansion/contraction plate configured to be expanded or contracted by a gas pressure such that the second member is moved horizontally to be brought into contact with or separated from the first member.

11. The substrate placement device according to claim 6, wherein the first member is a first ceramic member connected to a lower surface of the stage, the second member is a second ceramic member connected to an upper surface of the cooling head, and a lower surface of the first ceramic member and an upper surface of the second ceramic member are brought into contact with or separated from each other.

12. The substrate placement device according to claim 11, wherein mating surfaces of the first ceramic member and the second ceramic member are mirror-finished.

13. The substrate placement device according to claim 11, wherein the second ceramic member has a plurality of recesses in the upper surface of the second ceramic member, and
wherein the substrate placement device further comprises:
a gas supply source configured to supply a heat transfer gas to the recesses when the first ceramic member and the second ceramic member are brought into contact with each other.

14. The substrate placement device according to claim 11, wherein an electrode is provided in any one of the first ceramic member and the second ceramic member, and
when a voltage is applied to the electrode, the one of the first ceramic member and the second ceramic member electrostatically attracts a remaining one of the first ceramic member and the second ceramic member.

15. The substrate placement device according to claim 11, wherein the contact/separation plate includes an expansion/contraction plate provided between the second ceramic member and the cooling head and a gas supply configured to supply a gas to the extraction/contraction member, and
when the gas is supplied to the expansion/contraction plate, the first ceramic member and the second ceramic member are brought into contact with each other by a pressure of the gas.

16. The substrate placement device according to claim 11, wherein the first ceramic member and the second ceramic member are made of any of alumina, sapphire, and aluminum nitride.

17. A film forming apparatus comprising:
a vacuum container;
the substrate placement device of claim 1 configured to place a substrate thereon in the vacuum container; and
a sputtered particle emitter configured to emit sputtered particles to the substrate placed on the substrate placement device.

18. A film forming method comprising:
providing a film forming apparatus including a vacuum container, a substrate placement device configured to place a substrate thereon in the vacuum container, and a sputtered particle emitter configured to emit sputtered particles to the substrate placed on the substrate placement device, the substrate placement device including a stage having a substrate placement surface on which the substrate is placed, and a cooling head provided to face a side of the stage opposite to the substrate placement surface and configured to be cooled to an extremely low temperature by a refrigerator;
bringing the stage and the cooling head into contact with each other;
placing the substrate on the stage which is brought into contact with the cooling head, and cooling the substrate;
separating the stage and the cooling head from each other; and
performing film formation on the substrate by emitting the sputtered particles while rotating the substrate placed on the stage.
